(19) United States
(12) Patent Application Publication
(10) Pub. No.: US 2011/0175660 A1
(43) Pub. Date: Jul. 21, 2011

(54) Semiconductor device, data transmission system and method of controlling semiconductor device

(75) Inventor: Tatsuya Matano, Tokyo (JP)

(73) Assignee: Elpida Memory, Inc., Tokyo (JP)

(21) Appl. No.: 12/929,329

(22) Filed: Jan. 14, 2011

(30) Foreign Application Priority Data
Jan. 15, 2010 (JP) 2010-007238

(51) Int. Cl. H03L 5/00; H03F 3/45

(52) U.S. Cl. 327/306; 330/252

(57) ABSTRACT

A semiconductor device includes an amplifier section that receives a small-amplitude signal in which data is updated in synch with a clock, and an output section coupled to the output of the amplifier section. In synch with the clock, the amplifier section increases the current of a current source at timings at which the logic level of the small-amplitude signal is capable of undergoing a transition, and decreases the current at timings at which there is no transition. In synch with the clock, the output section drives a load by decreasing output impedance at timings at which the logic level of output data of the amplifier section is capable of undergoing a transition, and prevents flow of a through-current by increasing output impedance at timings at which the logic level does not undergo a transition.

### TECHNICAL FIELD

### Reference to Related Application

This application is based upon and claims the benefit of the priority of Japanese patent application No. 2010-007238, filed on Jan. 15, 2010, the disclosure of which is incorporated herein in its entirety by reference thereto. The present invention relates to a semiconductor device, a data transmission system and a method of controlling a semiconductor device. More particularly, the invention relates to a semiconductor device having an amplifier for amplifying an input signal in which data is updated in synch with a clock, a data transmission system for transmitting data in synch with sending and receiving sides, and a method of controlling a semiconductor device.

### BACKGROUND

In the field of semiconductor devices, low power consumption is sought while supporting an increase in the scale of circuitry integrated on a single chip and an increase in the data processing speed of semiconductor devices. In particular, owing to an increase in the scale of circuitry integrated on a single chip, the chip size of the semiconductor chip tends to increase and so does the length of the transmission line relating to data. On the other hand, in order to meet the market demand for higher data processing speed and lower power consumption, there is a need to transfer data within a chip at high speed and with little consumption of power. For example, in a synchronous DRAM (Dynamic Random-Access Memory), it is required that read data and write data be transferred between memory cell arrays of multiple banks and a data input/output terminal at high speed and low power consumption.

Patent Document 1 describes a liquid-crystal driving device in which, in an output circuit having a differential section and an output section, the bias current of the differential section (the current of a current source) is increased or decreased depending upon the size of the output load, and an output node of the output section is provided with a variable resistor and the resistance value of the variable resistor is increased or decreased depending upon the size of the output load, thereby preventing ringing in a case where the load is large and preventing overshoot in a case where the load is small.

### [Patent Document 1]

Japanese Patent Kokai Publication No. H-11-85113A, which corresponds to US Patent Application Publication No. US2001/0013851A1.

### SUMMARY

The analysis below is given by the present invention. In order to transmit data within a chip at high speed and low power consumption while there is an increase in the chip size of a semiconductor chip, a conceivable approach is to transmit data using a low-amplitude data signal and, on the receiving side, output the data signal upon returning the low-amplitude data signal to a data signal having an amplitude ideal for data processing. If the amplitude value of the data transmitted is made small, the time needed to charge and discharge the transmission line can be shortened and the charge/discharge current can be reduced.

In such case, using the differential circuit described in Patent Document 1 as the circuit on the receiving side is conceivable. If the differential circuit is used on the receiving side, it is possible to reduce the amplitude value of the signal that is output on the transmitting side, the charge/discharge current of the data transmission line can be reduced and the charge/discharge time of the data transmission line can be shortened. However, the smaller the amplitude of the received signal (the smaller the difference potential of signal transition), the more the current-source current (bias current) of the differential circuit that receives the data must be increased; otherwise, it will not be possible to amplify and output the data in a short time. Furthermore, the smaller the amplitude of the received signal, the smaller the amplitude of an internal signal that is output from the output node of the differential section and the larger the through-current of the output signal, which is constituted by a CMOS inverter that receives the internal signal. Although increasing the number of CMOS inverter stages is conceivable, the power consumed by the plurality of CMOS inverters per se increases.

From this point of view, Patent Document 1 does not disclose an amplifier that amplifies the input signal at high speed and that consumes little power even in a case where the amplitude of the input signal is small.

According to a first aspect of the present invention, there is provided a semiconductor device that comprises: a first amplifier comprising an amplifier section that amplifies an input signal and an output section including an input node coupled to an output node of the amplifier section; in relation to sensing of one item of information, a first control signal that controls activation of the first amplifier and a second control signal synchronized to transitions of the input signal. The input signal has first differential voltage indicated by a first potential corresponding to a first item of information and a second potential corresponding to a second item of information. The first amplifier outputs a second differential voltage, which has an absolute value larger than that of the first differential voltage, from the output node of the output section. The amplifier section includes a first current source, which is necessary for sensing the input signal, controlled by the first control signal, and a second current source, which is a current source larger than the first current source, controlled by the second control signal. The output section includes, as output impedance values thereof, a first impedance value and a second impedance value, either of which is selected by the second control signal, the second impedance value having an absolute value smaller than that of the first impedance value. The amplifier section is activated by the first control signal. The output section outputs, as the first impedance value, an output signal having the second differential voltage corresponding to the input signal having the first differential voltage. With the first amplifier in the activated state, the amplifier section and the output section, using the second current source and the second impedance value under the control of the second control signal, output, as the second impedance value, the output signal having the second differential voltage corresponding to transitions of the input signal having the first differential voltage.

According to a second aspect of the present invention, there is provided a data transmission system that comprises: a transmitting unit that updates data in synch with a clock and transmits the data to a transmission line as a small-amplitude signal; a receiving unit, which is coupled to the transmission line, including an amplifier section that receives and amplifies the small-amplitude signal, and an output section that includes an input node coupled to an output node of the amplifier section and outputs a signal from an output node as a data signal having an amplitude value the voltage whereof is larger than that of the amplified small-amplitude signal; and a reception control unit which, in relation to sensing of one item of information, and in an interval in which the amplifier section is activated, increases and decreases a current, which passes through the amplifier section, in synch with the clock, and increases and decreases an output impedance value of the output section in synch with the clock.

According to a third aspect of the present invention, there is provided a method of controlling a semiconductor device that comprises an input signal having a first differential voltage, and a first amplifier having as an operating voltage a second differential voltage larger than the first differential voltage. The method comprises: activating the first amplifier by a first control signal; and in relation to sensing of a first item of information, and in a state in which activation of the first amplifier is maintained, controlling sensing capability by raising capability of a current source, which is necessary for sensing of the input signal that drives the first amplifier, by a second control signal related to transitions of the input signal, and controlling, by the second control signal, the impedance value of a driver for receiving a signal, which has been output to an output node of the first amplifier, at an input node and outputting the signal from an output node as a signal having the second differential voltage.

In accordance with the present invention, a semiconductor device is provided with a second current source controlled by a second control signal synchronized to the times at which an input signal undergoes a transition. As a result, the current of an amplifier section can be increased or decreased by the second control signal synchronized to the transitions of the input signal. In addition, since an increase or decrease in the output impedance of an output section can be controlled by the second control signal, the amplifier can be operated at high speed in synch with the transitions of the input signal and power consumption can be reduced. Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram illustrating the entirety of a semiconductor device according to a first exemplary embodiment of the present invention;

FIG. 2 is a block diagram illustrating the entirety of an interface portion between a memory cell array and a data input/output terminal in the semiconductor device according to the first exemplary embodiment;

FIG. 3 is a circuit block diagram of a read-data transmission circuit in the semiconductor device according to the first exemplary embodiment;

FIG. 4 is a circuit block diagram of a write-data transmission circuit in the semiconductor device according to the first exemplary embodiment;

FIG. 5 is a circuit block diagram of a data receiver according to the first exemplary embodiment;

FIG. 6 is an operation waveform diagram illustrating read-data transmission according to the first exemplary embodiment;

FIG. 7 is a circuit block diagram (related diagram) illustrating a data receiver according to an example for comparison purposes;

FIG. 8 illustrates simulated operation waveform diagrams of a data amplifier according to (a) an example for comparison purposes and (b) the first exemplary embodiment, respectively;

FIG. 9 is a diagram illustrating a comparison of results of simulations according to an example for comparison purposes and the first exemplary embodiment;

FIG. 10 is a circuit block diagram illustrating a data transmission circuit according to a second exemplary embodiment of the present invention;

FIG. 11 is a block diagram illustrating a data transmission system according to a third exemplary embodiment of the present invention; and

FIG. 12 is a block diagram illustrating a data transmission system according to a fourth exemplary embodiment of the present invention.

### PREFERRED MODES

In accordance with a representative exemplary embodiment of the present invention, an input signal of a first amplifier has a differential voltage indicated by a first potential (e.g., a low-level potential) corresponding to first information (e.g., data is “0”) and a second potential (e.g., a high-level potential) corresponding to second information (e.g., data is “1”). The first amplifier makes the first differential voltage a second differential voltage, the absolute value of which is larger than that of the first differential voltage, and outputs the second differential voltage. Furthermore, the first amplifier increases or decreases the current value of a current source based upon a second control signal related to the transitions of the input signal. When the input signal undergoes a transition, therefore, the current value of the current source is increased and the input signal can be amplified at high speed. Further, when the input signal does not undergo a transition, power consumption can be reduced by reducing the current value of the current source while the output voltage of the amplifier section is maintained.

Further, the output impedance of an output section that further amplifies the output voltage of the amplifier section is controlled by the second control signal. When the logic level of the output undergoes a transition, the output impedance of the output section is reduced and the load is driven at high speed. On the other hand, when the logic level of the output does not undergo a transition, the output impedance of the output section is increased. Even if the output voltage of the amplifier section is an intermediate voltage, therefore, the output voltage of the output section can be maintained while a through-current that flows into the output section is reduced. Accordingly, even if the input signal is a small-amplitude signal, a data signal having high-level and low-level voltages of a peripheral circuit can be amplified and output at high speed and with little consumption of power.

It should be noted that a data strobe signal, which updates data that is output to a transmission line from a first circuit on the side that outputs the input signal, can be used as the second control signal for controlling the current of the amplifier section and the output impedance value on the receiving side. The second control signal that controls the amplifier section and the second control signal that controls the output section taking into consideration data transmission time and amplification time of the amplifier section can employ phase-shifted second control signals each of which lags behind the data strobe signal used to update the data that the first circuit outputs to the transmission line.

Exemplary Embodiments of the present invention will be described in detail below with reference to the drawings.

### First Exemplary Embodiment

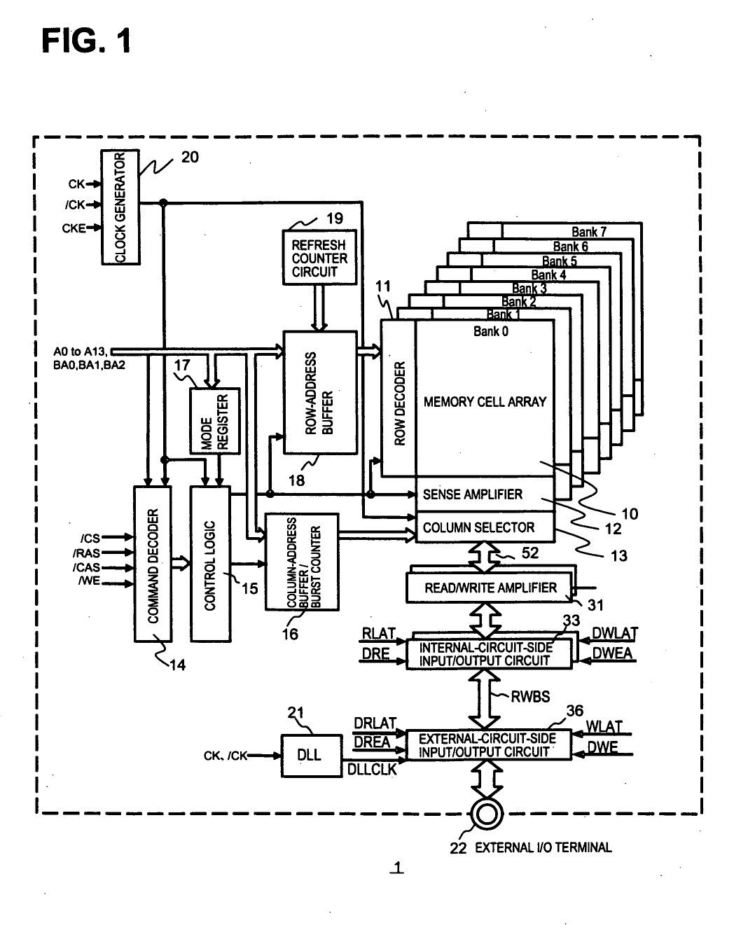

FIG. 1 is a block diagram illustrating the entirety of a semiconductor device 1 according to a first exemplary embodiment of the present invention. The semiconductor device 1 of FIG. 1 is a synchronous DRAM such as a DDR SDRAM (Double Data-Rate Synchronous DRAM). As shown in FIG. 1, the semiconductor device 1 includes a memory cell array 10; a row decoder 11 for decoding a row address and driving a selected word line (not shown); a sense amplifier 12 for sensing data of a memory cell (not shown) selected from within the memory cell array; and a column selector 13 for outputting, to the exterior of the memory cell array 10, data selected based upon a column address from among multiple items of data sensed by the sense amplifier 12. The semiconductor device 1 is provided with eight memory cell arrays 10 of memory banks Bank0 to Bank7. The row decoder 11, sense amplifier 12 and column selector 13 are provided for every memory cell array.

A clock generator 20 generates an internal operation clock from an externally applied non-inverted clock signal CK, an inverted clock signal /CK and a clock-enable signal CKE. A command decoder 14 decodes an external applied chip select signal /CS, a row-address strobe signal /RAS, a column-address strobe signal /CAS and a write-enable signal /WE, and interprets commands such as read and write commands applied to the semiconductor device 1 from an external memory controller or the like. On the basis of a command interpreted by the command decoder 14 and the status of a mode register 17, control logic 15 outputs signals, which are necessary in order to execute commands, to each portion of the semiconductor device 1 in synch with the clock generated by the clock generator 20. External address input terminals A0 to A13 and bank address input terminals BA0, BA1, BA2 are connected to the mode register 17, a column-address buffer/burst counter 16 and a row-address buffer 18 via an internal address bus. When a mode register setting command is applied thereto, the mode register 17 sets data, which has been applied from the internal address bus, to a register. When a bank active ACT command is applied thereto, the row-address buffer 18 latches the row address and outputs the row address to the row decoder 11. When a read command and a write command are applied to the column-address buffer/burst counter 16, the column-address buffer/burst counter 16 latches the column address, decodes the address and selects the column selector 13. Further, when a burst trigger and a burst write command are applied, the column-address buffer/burst counter 16 counts the column address based upon a designated burst length. A refresh counter circuit 19 counts up a refresh address. Based upon the external clock signals applied from the external clock terminals CK, /CK, a DLL 21 generates a clock signal that is in phase with the external clock signals and controls the timing of data input/output from an external I/O terminal 22.

Further, a read/write amplifier 31 and an internal-circuit-side input/output circuit 33 are provided externally of the memory cell arrays 10 for each one of the eight memory cell arrays 10 of banks Bank0 to Bank7. When a read command is executed, the read/write amplifier 31 senses data of a memory cell read out to the external of the memory cell arrays 10 via the sense amplifier 12, column selector 13 and an I/O line 52. Further, when a write command is executed, the read/write amplifier 31 writes, to the memory cell array 10, write data that has been input from the external I/O terminal 22 via an external-terminal-side input/output circuit 36, a read/write data bus RWBS and the internal-circuit-side input/output circuit 33.

When a read operation is performed, the internal-circuit-side input/output circuit 33 outputs data, which has been sensed by the read/write amplifier 31, to the read/write data bus RWBS. When a write operation is performed, the internal-circuit-side input/output circuit 33 accepts write data from the read/write data bus RWBS and sends the write data to the read/write amplifier 31.

Connected to the internal-circuit-side input/output circuit 33 as signals that control the read operation are a read-data strobe signal RLAT, which is a signal for latching the data that is output by the read/write amplifier 31, and a read buffer output-enable signal DRE, which is signal enabling output to the read/write data bus RWBS.

Further connected to the internal-circuit-side input/output circuit 33 as signals that control the write operation are a write-data receiver enable signal DWEA and a write-data strobe signal DWLAT. In this exemplary embodiment, the current value of a differential amplifier included in the data receiver and the output impedance of the output section of the differential amplifier are controlled by the write-data strobe signal DWLAT. The details of implementation and operation will be described later.

The read/write data bus (transmission line) RWBS is a parallel data bus connecting each of the memory cell arrays 10 and each of the external I/O terminals 22. The read/write data bus RWBS is a bus for transmitting small-amplitude signals.

The external-terminal-side input/output circuit 36 is provided in correspondence with each external I/O terminal 22 (only one external I/O terminal 22 is shown in FIG. 1). When the read operation is performed, the external-terminal-side input/output circuit 36 amplifies read data of small-amplitude signals, which have entered in parallel from the read/write data bus RWBS, to digital-signal amplitude used in ordinary data processing. Further, the external-terminal-side input/output circuit 36 converts this data to serial data in synch with clock DLLCLK that is output by the DLL 21 and outputs the data from the external I/O terminal 22. When the write operation is performed, the external-terminal-side input/output circuit 36 converts write data, which has been accepted from the external I/O terminal 22 in synch with the clock DLLCLK output by the DLL 21, to parallel data and outputs this data to the read/write data bus RWBS.

Connected to the external-terminal-side input/output circuit 36 as signals for controlling the read operation are a read-data receiver enable signal DREA and a read-data strobe signal DRLAT. It should be noted that the signal DRLAT is a read-data strobe signal lagging in phase behind the signal RLAT. Although there is a phase shift, the signals RLAT and DRLAT are synchronized signals in the same system. In this exemplary embodiment, the current value of the differential amplifier included in the data receiver and the output impedance of the output section of the differential amplifier are controlled by the read-data strobe signal DRLAT. The details of implementation and operation will be described later.

Connected to the external-terminal-side input/output circuit 36 as signals for controlling the write operation are a write-data strobe signal WLAT, which is a signal for latching the data that is outputted to the read/write data bus RWBS, and a write buffer output-enable signal DWE, which is signal enabling output to the read/write data bus RWBS. It should be noted that the signal WLAT is a write-data strobe signal leading in phase ahead the signal DWLAT. Although there is a phase shift, the signals WLAT and DWLAT are synchronized signals in the same system.

The external I/O terminal 22, which is the input/output terminal of the write data and read data, is illustrated as only a single representative terminal in FIG. 1. With a synchronous DRAM such as a DDR, however, generally the number of these terminals is 4 to 16. When the write operation is performed, data that has been input serially from the 4 to 16 external I/O terminals 22 is converted to parallel data by the external-terminal-side input/output circuit 36, the data is transferred to the applicable internal-circuit-side input/output circuits 33 via the read/write data bus RWBS and the data is written to the memory cell arrays 10. When the read operation is performed, read data that has been read out to the external-terminal-side input/output circuit 36 as parallel data via the read/write data bus RWBS is converted to serial data by the external-terminal-side input/output circuit 36 and is output from the 4 to 16 external I/O terminals 22.

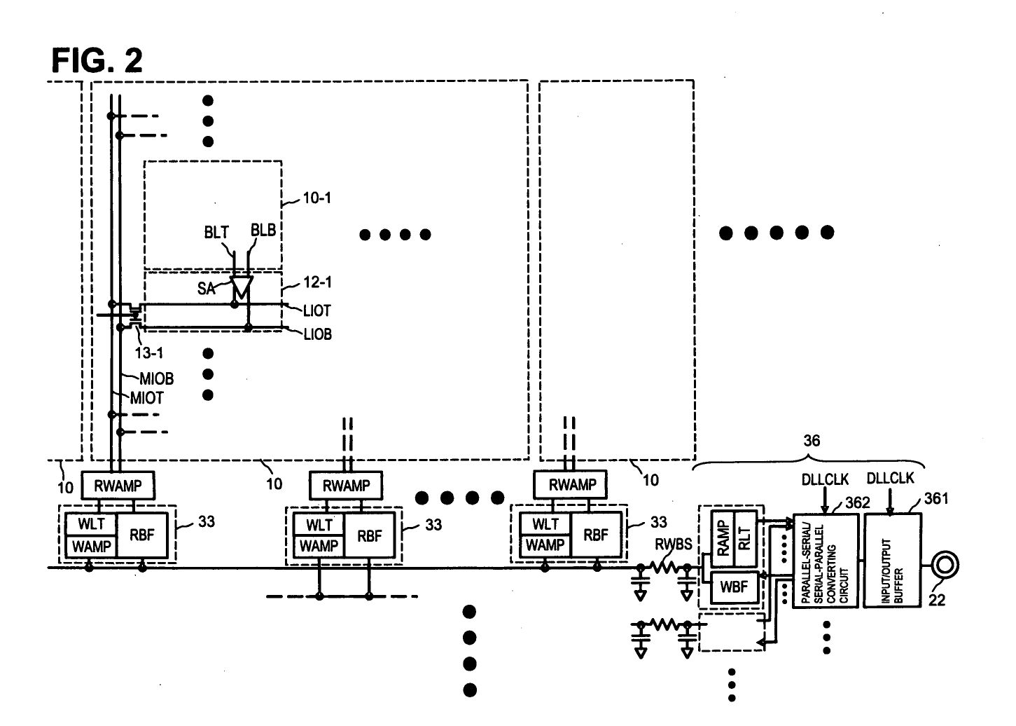

FIG. 2 is a block diagram of an interface portion between memory cell arrays 10 and data input/output terminal 22 in the semiconductor device according to the first exemplary embodiment. Of the eight memory cell arrays 10, only three are illustrated in FIG. 2 and the other memory cell arrays are not shown. Further, of the 4 to 16 external I/O terminals 22, only one is shown in FIG. 2 and the others are not shown.

In FIG. 2, the memory cell arrays 10 indicate areas in each of which a memory array of a single bank is placed. The memory cell array 10 of the single bank is divided into a plurality of partial areas 10-1 and every partial area 10-1 is provided with a sense amplifier row 12-1 in which sense amplifiers SA are disposed. Bit lines BLT, BLB are connected to local IO lines LIOT, LIOB via the sense amplifier SA. The local IO lines LIOT, LIOB are connected to main IO lines MIOT, MIOB via a read/write gate 13-1, and the main IO lines MIOT, MIOB are connected to a read/write amplifier RWAMP (which corresponds to read/write amplifier 31 in FIG. 1). It should be noted that a number of the partial areas 10-1 are disposed in the form of a matrix in the memory cell array 10 of the single bank, and that the sense amplifier row 12-1 and local IO lines LIOT, LIOB are provided in correspondence with each partial area 10-1. Although only one pair of the main IO lines MIOT, MIOB is shown in FIG. 2, a plurality of main IO line pairs MIOT, MIOB are provided in parallel within each memory cell array 10 in correspondence with the matrix-arrayed partial areas 10-1. A plurality of the read/write amplifiers RWAMP are provided in correspondence with each main IO line pair MIOT, MIOB.

The internal-circuit-side input/output circuit 33 has a read-data buffer RBF, a write-data latch WLT and a write-data receiver WAMP. The read-data buffer RBF has a latch circuit for temporarily storing read data that has been read out of the read/write amplifier RWAMP, and a drive circuit for outputting the data, which is held by the latch circuit, to the read/write data bus RWBS as a small-amplitude signal. The write-data receiver WAMP senses latch data sent as a small-amplitude signal from the external-terminal-side input/output circuit 36 via the read/write data bus RWBS when a write command is executed. It should be noted that although the write-data receiver enable signal DWEA and the write-data strobe signal DWLAT are connected to the write-data receiver WAMP as control signals, these are not shown in FIG. 2. The write-data latch WLT is a latch for temporarily storing the data sensed by the write-data receiver WAMP at execution of the write command until the data is written to the memory cell array 10. It should be noted that a plurality of the internal-circuit-side input/output circuits 33 are provided for every bank in correspondence with each read/write amplifier RWAMP.

The read/write data bus RWBS is a bidirectional bus comprising a transmission line of a plurality of bits and connects the plurality of internal-circuit-side input/output circuits 33 provided in correspondence with each memory cell array 10 with the plurality of external-terminal-side input/output circuits 36 provided in correspondence with each external I/O terminal 22. A plurality of the internal-circuit-side input/output circuits 33 are connected, bank by bank, to the single read/write data bus RWBS. Further, since the read/write data bus RWBS is wired from the internal-circuit-side input/output circuit 33 provided in close proximity to the memory cell array 10 of each bank to the external-terminal-side input/output circuit 36 provided in close proximity to the external I/O terminal 22, the length of the wiring of read/write data bus RWBS corresponds to the length of the side of the semiconductor chip of semiconductor device 1.

The external-terminal-side input/output circuit 36, which is provided for every external I/O terminal 22, includes a read/write data bus interface having a read-data receiver (first amplifier) RAMP, a read-data latch RLT and a write-data buffer WBF; a parallel-serial/serial-parallel converting circuit 362; and an input/output buffer 361.

The read-data receiver (first amplifier) RAMP senses the small-amplitude signal of read/write data bus RWBS when the read command is executed. Although the read-data receiver enable signal DREA and read-data strobe signal DRLAT are connected to the read-data receiver RAMP as control signals, these are not shown in FIG. 2. The read-data latch RLT is a latch for temporarily storing the data sensed by the read-data receiver RAMP at execution of the read command. The write-data buffer WBF has a latch circuit for temporarily storing data resulting from a serial-to-paralled conversion performed by the parallel-serial/serial-parallel converting circuit 362, and a drive circuit for outputting the data held by this latch circuit to the read/write data bus RWBS as a small-amplitude signal.

At execution of a read command, the parallel-serial/serial-parallel converting circuit 362 subjects data latched temporarily by the read-data latch RLT to a parallel-to-serial conversion in synch with DLLCLK and outputs the serial data to the input/output buffer 361. Further, at execution of a write command, the parallel-serial/serial-parallel converting circuit 362 converts data that has entered from the input/output buffer 361 to parallel data in synch with DLLCLK and stores the parallel data in the latch circuit of write-data buffer WBF.

At execution of the read command, the input/output buffer 361 outputs the serial data, which results from the conversion by the parallel-serial/serial-parallel converting circuit 362, from the external I/O terminal 22. At execution of the write command, the input/output buffer 361 accepts data that has entered from the external I/O terminal 22 and sends this data to the parallel-serial/serial-parallel converting circuit 362. Furthermore, in synch with the data signal that is input to and output from the external I/O terminal 22, a data strobe signal is input to and output from a DQS terminal (not shown) of the input/output buffer 361. It should be noted that the data strobe signal input to and output from the DQS terminal is a signal different from the read-data strobe signals RLAT, DRLAT and write-data strobe signals WLAT, DWLAT used in transmission in the read/write data bus RWBS internally of the semiconductor device 1.

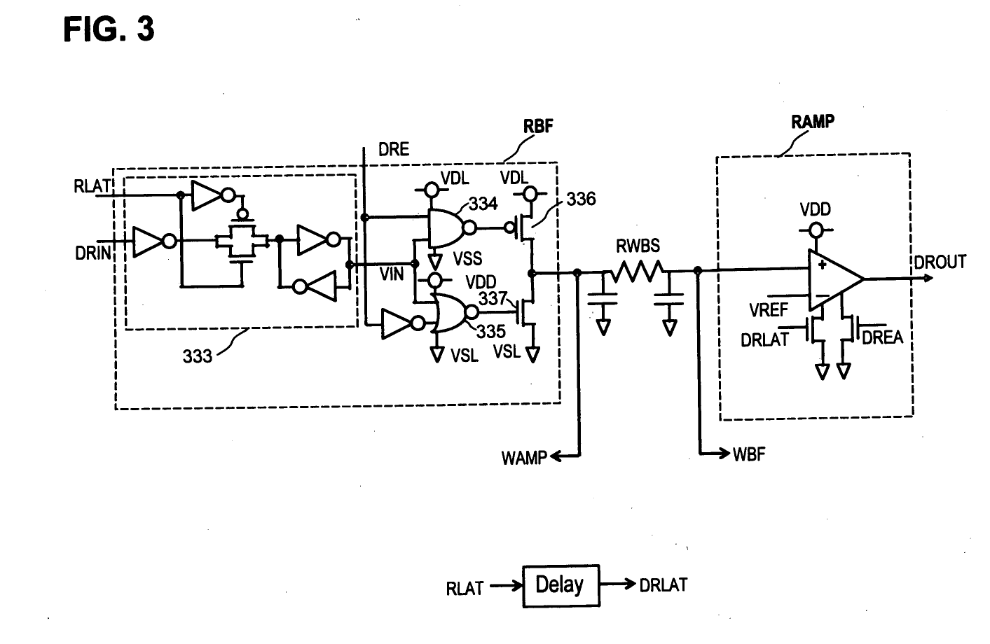

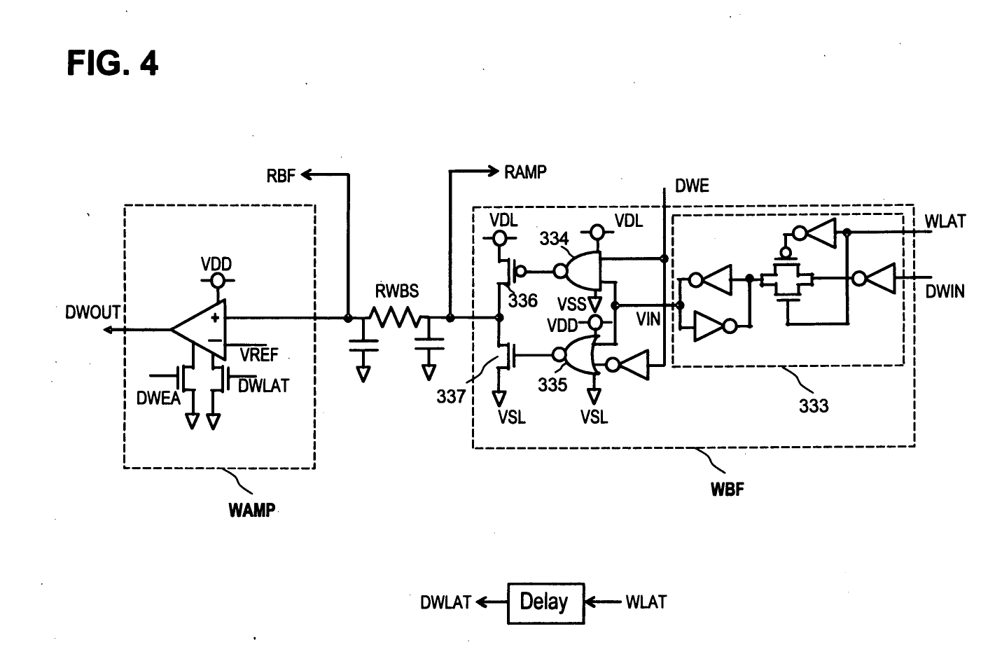

FIG. 3 is a circuit block diagram illustrating the internal configurations of the read-data buffer RBF and read-data receiver RAMP, which are associated with transmission of read data, in the internal-circuit-side input/output circuit 33 and external-terminal-side input/output circuit 36 associated with the read/write data bus RWBS in FIG. 2. FIG. 3 merely illustrates the fact that the write-data buffer WBF and write-data receiver WAMP are connected to the read/write data bus RWBS; the write-data buffer WBF and write-data receiver WAMP themselves are not shown. FIG. 4 is a block diagram illustrating the internal configurations of the write-data buffer WBF and write-data receiver WAMP associated with transmission of write data. FIG. 4 merely illustrates the fact that the read-data buffer RBF and read-data receiver RAMP are connected to the read/write data bus RWBS; the read-data buffer RBF and read-data receiver RAMP themselves are not shown.

With regard to the circuitry in which a high-potential power source VDL and low-potential power source VSL of the small-amplitude signal are supplied as power in the circuits shown in FIGS. 3 and 4, the power sources are indicated as VDL and VSL. However, the power source of the circuits supplied with VDD and VSS is shown only in part. Accordingly, in the circuit shown in FIG. 3, the power source of the circuit in which the power system is not indicated is supplied with VDD and VSS. It should be noted that the voltage of the high-potential power source VDL, which is lower than the voltage of the power source VDD, is an internal power source generated within the semiconductor device 1. Further, it is noteworthy that the voltage of the low-potential power source VSL, which is a voltage equal to or greater than the voltage of the power source VSS, is an internal power source generated within the semiconductor device 1.

In FIG. 3, the read-data buffer RBF has a pre-buffer circuit that includes a latch circuit 333, a NAND gate 334 and a NOR gate 335, and a buffer circuit that includes a P-channel MOS transistor 336 and an N-channel MOS transistor 337. The latch circuit 333 accepts an output signal DRIN of the read/write amplifier RWAMP (see FIG. 2) in synch with the rising edge of the read-data strobe signal RLAT. When the latch signal RLAT is at the low level, the latch circuit 333 holds data. Accordingly, the data held by the latch circuit 333 is updated in synch with the rising edge of the read-data strobe signal RLAT.

The NAND gate 334, NOR gate 335, P-channel MOS transistor 336 and N-channel MOS transistor 337 function as a driver. When the read buffer enable signal DRE is at the high level, the data held in the latch circuit 333 is output to the read/write data bus (transmission line) RWBS as a small-amplitude signal. When the read buffer enable signal DRE is at the low level, the P-channel MOS transistor 336 and N-channel MOS transistor 337 turn off and the output of the read-data buffer RBF takes on a high impedance. Accordingly, when the read buffer enable signal DRE is at the high level, the data that is output from the read-data buffer RBF to the read/write data bus RWBS is updated in synch with the rising edge of the read-data strobe signal RLAT. When the read-data strobe signal RLAT is at the low level, the data that is output from the read-data buffer RBF to the read/write data bus RWBS does not change.

In the circuit shown in read-data buffer RBF, the high-potential power source terminal of the NAND gate 334 is connected to the internal power source VDL and the low-potential power source terminal is connected to the power source VSS. The high-potential power source terminal of the NOR gate 335 is connected to the power source VDD and the low-potential power source terminal is connected to the power source VSL. The source of the P-channel MOS transistor 336 constituting the buffer circuit is connected to the internal power source VDL, and the source of the N-channel MOS transistor 337 is connected to the internal power source VSL.

Since the P-channel MOS transistor 336 and N-channel MOS transistor 337 constituting the driver circuit have their sources connected to VDL and VSL, respectively, the signal that is output from the read-data buffer RBF to the read/write data bus RWBS is a small-amplitude signal of the high-potential VDL and low-potential VSL. This is a signal having an amplitude smaller than that of a driver circuit whose power source is connected to power sources VDD and VSS. Accordingly, high-speed signal propagation becomes possible by reducing the charge/discharge current of the read/write data bus RWBS and lowering the amplitude.

Further, the low-potential power source of NAND gate 334 is supplied from VSS and the high-potential power source of NOR gate 335 is supplied from VDD. Therefore, even though the potential difference between VDL and VSL is small, the first driver, which comprises the P-channel MOS transistor 336 and N-channel MOS transistor 337, will operate if the potential difference between VDL and VSS and the potential difference between VDD and VSL are voltages that exceed the transistor threshold value of the P-channel MOS transistor 336 and the transistor threshold value of the N-channel MOS transistor 337, respectively.

The read-data receiver (first amplifier) RAMP has a differential circuit, which has a non-inverting signal input terminal to which the read/write data bus (transmission line) RWBS is connected and an inverting signal input terminal to which the reference voltage VREF is connected, for comparing the small-amplitude signal transmitted through the read/write data bus RWBS with the reference voltage VREF. An intermediate voltage approximately one-half of VDL and VSL, which are the power sources of the driver circuit that outputs the small-amplitude signal, is applied as the reference voltage VREF. The reference voltage VREF can be generated by dividing the voltages VDL and VSL using a resistor.

With regard to the signals that control the operation of the read-data receiver, the read-data receiver enable signal DREA is applied as a first control signal and the read-data strobe signal DRLAT is applied as a second control signal. It should be noted that the signal DRLAT is a read-data strobe signal that is a result of phase-delaying the read-data strobe signal RLAT by a delay circuit Delay. Although DRLAT is generated from RLAT in FIG. 3, the phase-shifted signals RLAT and DRLAT may be generated from the clock signal that is the basis of the signal RLAT. When the read-data receiver enable signal DREA is at the high level, power is supplied to the differential circuit of the read-data receiver. When the read-data receiver enable signal DREA is at the low level, the supply of power to the differential circuit is halted and power consumption is reduced. Further, the read-data strobe signal DRLAT controls the operation of the read-data receiver in synch with the timing at which the data that enters from the read/write data bus RWBS is updated. The output signal DROUT of the read-data receiver RAMP is connected to the read-data latch RLT.

The write-data buffer WBF and write-data receiver WAMP shown in FIG. 4 are basically the same as the read-data buffer RBF and read-data receiver RAMP of FIG. 3 in terms of structure and operation except for the fact that whereas the read-data buffer RBF and read-data receiver RAMP transmit data from the side of the internal circuitry to the side of the external terminal through the read/write data bus RWBS, the write-data buffer WBF and write-data receiver WAMP transmit data from the side of the external terminal to the side of the internal circuitry. Accordingly, a description of these buffers would be a repeat of the description of FIG. 3 and is not rendered here. The write-data receiver enable signal DWEA is a first control signal and the write-data strobe signal DWLAT is a second control signal.

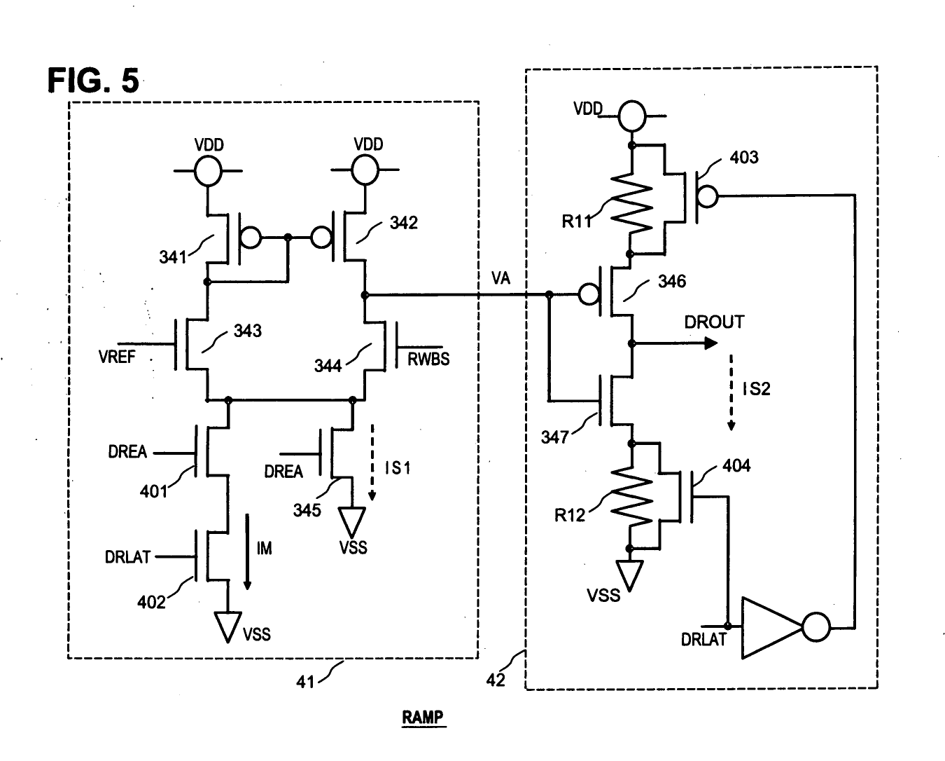

FIG. 5 is a circuit block diagram illustrating the internal circuitry of the read-data receiver RAMP shown in FIG. 3. It should be noted that the write-data receiver WAMP of FIG. 4 also is an amplifier (first amplifier) the input signal to which is the small-amplitude signal transmitted through the read/write data bus RWBS and has the same circuit structure and operates in the same manner.

The read-data receiver RAMP in FIG. 5 has an amplifier section 41 and an output section 42. The amplifier section 41 amplifies the small-amplitude signal that enters from the read/write data bus RWBS. The output section 42 wave-shapes the signal whose amplitude has been amplified to the intermediate-level voltage, and which is output from the amplifier section 41, to a CMOS-level (high level is VDD, low level is VSS) logic signal and outputs the logic signal from output terminal DROUT.

The amplifier section 41 has a differential pair comprising N-channel MOS transistors 343, 344; a load circuit comprising P-channel MOS transistors 341, 342; and a current source circuit comprising N-channel MOS transistors 401, 402, 345. The differential pair comprising the N-channel MOS transistors 343, 344 has its sources tied together. The gate of the N-channel MOS transistor 343 is connected to the reference voltage VREF, and the gate of the N-channel MOS transistor 344 is connected to the read/write data bus RWBS. The P-channel MOS transistor 341 constituting the load circuit has its drain and gate connected to the drain of the N-channel MOS transistor 343 and has its source connected to the power source VDD. Further, the P-channel MOS transistor 342 has its gate connected in common with the gate of the P-channel MOS transistor 341, its source connected to the power source VDD and its drain connected to the drain of the N-channel MOS transistor 344 and to output node VA of amplifier section 41.

The current source circuit has a first current source and a second current source. The first current source has an N-channel MOS transistor 345 having a source connected to power source VSS, a gate connected to the read-data receiver output enable signal DREA and a drain connected to the sources of the differential pair. The second current source has N-channel MOS transistors 401 and 402 connected serially between the sources of the differential pair and the power source VSS. The read-data receiver output enable signal DREA and the read-data strobe signal DRLAT are connected to the gates of the N-channel MOS transistors 401 and 402, respectively.

The read-data receiver output enable signal DREA, which is a signal maintained at the high level during operation of the read-data receiver RAMP, falls to the low level when data reception by the read-data receiver RAMP is completed. The first current source, therefore, continues to supply current IS1 to the differential pair during the operation of the read-data receiver RAMP. On the other hand, the read-data strobe signal DRLAT, which is a signal that takes on the high level when the data on the read/write data bus RWBS connected to the gate of the N-channel MOS transistor 344 constituting the differential pair is updated, is maintained at the low level at timings where the data on the read/write data bus RWBS does not change. Accordingly, the second current source operates so as to pass a current IM at timings where the data on the read/write data bus RWBS constituting the input signal to the differential pair can change, and to halt supply of the current IM at timings where the data does not change. It should be noted that the read-data strobe signal DRLAT is a signal that changes while the amplifier section 41 is in operation. Therefore, in order to so arrange it that the switching of the read-data strobe signal DRLAT will not adversely influence the differential pair as noise, the N-channel MOS transistor 401 is connected between the differential pair and the drain of the N-channel MOS transistor 402 to the gate of which the read-data strobe signal DRLAT is connected.

The output section 42 includes a P-channel MOS transistor 346 and an N-channel MOS transistor 347 having gates connected in common with the output node VA of amplifier section 41 and drains connected in common with the output terminal DROUT; a resistor R11 connected between the source of the P-channel MOS transistor 346 and the power source VDD; a P-channel MOS transistor 403 having a source connected to the power source VDD and a drain connected to the source of the P-channel MOS transistor 346; a resistor R12 connected between the source of the N-channel MOS transistor 347 and the power source VSS; and an N-channel MOS transistor 404 having a source connected to the power source VSS and a drain connected to the source of the N-channel MOS transistor 347.

Voltages of high level and low level that are output from the output node VA of amplifier section 41 are signals of an intermediate potential (third differential voltage) that do not reach VDD, VSS, respectively. Accordingly, there are cases where a through-current flows between the power sources VDD and VSS via the transistors 346, 347 of the output section 42. In order to suppress through-current and reduce power consumption, the resistors R11, R12 are provided between the sources of transistors 346, 347 and the power sources VDD, VSS. However, when power-source current is supplied via the resistors R11, R12 at all times, the load driving capability of the output section declines, charge/discharge time of the load at output terminal DROUT lengthens and an increase in speed is hampered. Accordingly, the transistors 403, 404 are provided in parallel with the resistors R11, R12, respectively, and conduction/non-conduction of the transistors 403, 404 is controlled by the read-data strobe signal DRLAT. The transistors 403, 404 are controlled so as to conduct at a timing where data sent to the read/write bus is updated and the logic level of the output node VA is capable of undergoing a transition, and so as to not conduct at a timing where the logic level of the output node VA does not change. It should be noted that it will suffice if the voltage at the output terminal DROUT can be maintained at the timing where the logic level of the output node VA does not change. Therefore, the output impedance values of the output section when the transistors 403, 404 conduct and do not conduct are made to differ by a factor of nine or more, and the through-current can be reduced by a factor of nine or more at the timing where the logic level of the output node VA does not change.

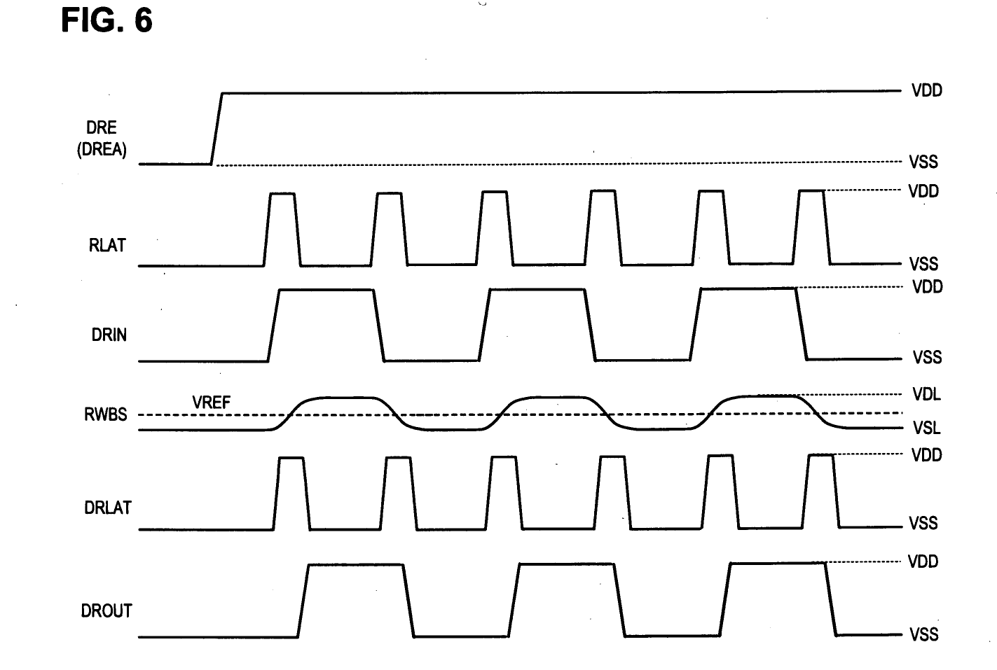

Next, the operation of the read-data receiver will be described in further detail with reference to an operation waveform diagram shown in FIG. 6 illustrating read-data transmission. The read buffer output-enable signal DRE, as described above with reference to FIG. 3, is a signal for controlling conduction/non-conduction of the read-data buffer RBF. When the signal is at the low level, the read-data buffer RBF takes on a high output impedance. When the signal is at the high level, data is output from the read-data buffer RBF to the read/write data bus RWBS. Further, the read-data receiver enable signal DREA is controlled to the same logic level at the same time as the read buffer output-enable signal DRE.

When the read buffer output-enable signal DRE first rises from the low level to the high level, the drive circuit of the read-data buffer RBF changes from an output high impedance state to the conductive state. At the same time, the read-data receiver enable signal DREA also rises from the low level to the high level, the first current source of the amplifier section 41 of read-data buffer RBF conducts and the differential pair is supplied with current. Under these conditions, the read-data strobe signal RLAT is at the low level and the data that is output from the read/data buffer is not updated. Further, the read-data strobe signal DRLAT, which lags in phase behind the read-data strobe signal RLAT, also is at the low level, the second current source (401, 402) of the amplifier section of read-data receiver RAMP does not conduct and the output impedance of the output section 42 remains high.

When the read-data strobe signal RLAT rises, the data held in the latch circuit 333 of the read-data buffer RBF is updated by the data DRIN, the updated data becomes a small-amplitude signal and is output to the read/write data bus RWBS. The read-data strobe signal DRLAT lagging in phase behind the signal RLAT is supplied to the read-data receiver 41, the second current source of the amplifier section 41 conducts over the interval in which the signal DRLAT is at the high level, the current of the amplifier section 41 increases from IS1 to IS1+IM, a change in the voltage level of the read/write data bus RWBS is sensed at high speed and amplification is performed. Further, over the interval in which the signal DRLAT is at the high level, the output section 42 lowers the output impedance value and drives the load of the output terminal DROUT at high speed. At the timing where the logic level of the small-amplitude signal on the read/write data bus RWBS received by the amplifier section 41 does not change, the read-data strobe signal DRLAT is at the low level. The current of the amplifier section 41, therefore, is suppressed to IS1 alone, the output impedance of the output section 42 increases and the through-current that flows into the output section 42 is suppressed. While the read data that has been read out of the memory cell array 10 is being transferred from the read-data buffer RBF to the read-data receiver RAMP, the read-data strobe signal DRLAT is controlled to the high and low levels in conformity with the timing at which the data on the read/write data bus RWBS is updated. As a result, at the timing at which the data is updated, the data on the read/write data bus RWBS is amplified at high speed and is output from the output terminal DROUT at a low impedance. At the timing at which there is no change in the data, power consumption can be reduced.

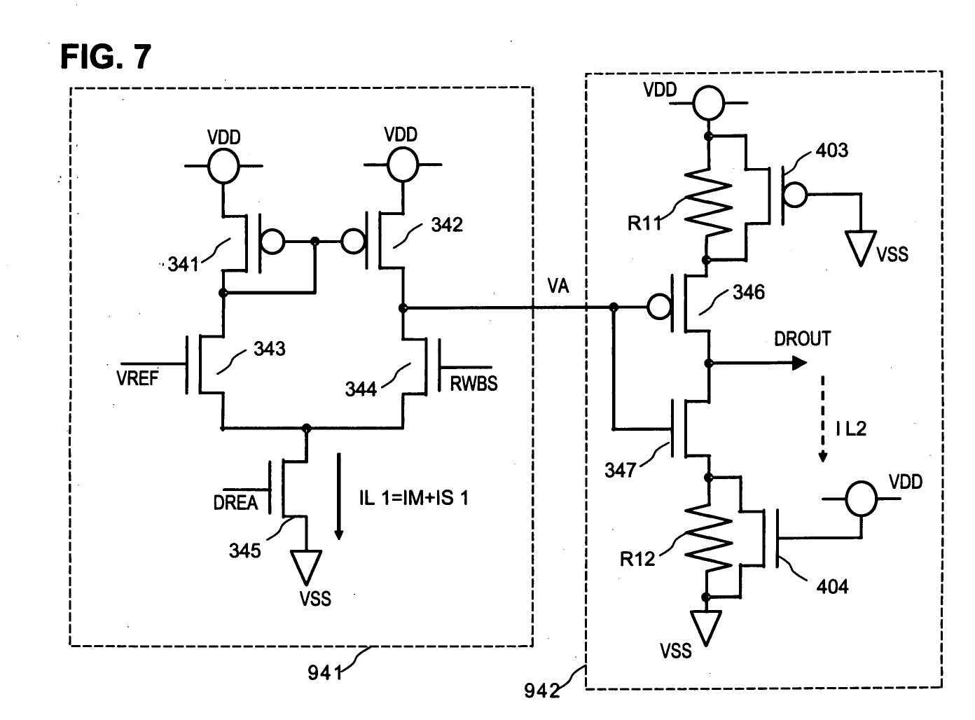

The results of simulations performed with regard to the first exemplary embodiment and an example for comparison purposes will be described with reference to FIGS. 7 to 9. FIG. 7 is a circuit block diagram of an example used for performing a comparison with the first exemplary embodiment. In comparison with the data receiver circuit of FIG. 5, the circuit of the comparison example in FIG. 7 has an amplifier section 941 which is devoid of the N-channel MOS transistors 401, 402 of the current source circuit. The transistor size of the N-channel MOS transistor 345 is enlarged correspondingly and a current whose total value is IL1=IM+IS1 flows in the first and second current sources of FIG. 5 at all times. Further, the gate of P-channel MOS transistor 403 in output section 942 is connected to VSS, the gate of N-channel MOS transistor 404 is connected to VDD and a current IL2 flows between the source and drain at all times. Other aspects of structure (inclusive of sizes of the transistors with the exception of transistor 345) and operation are the same as those of the data receiver according to the first exemplary embodiment shown in FIG. 5.

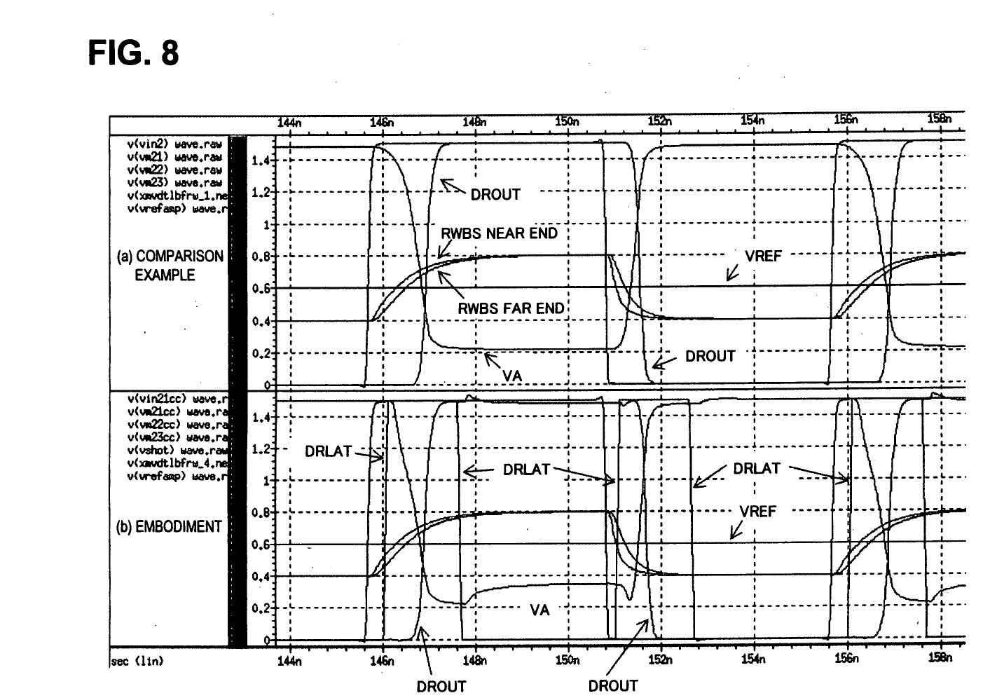

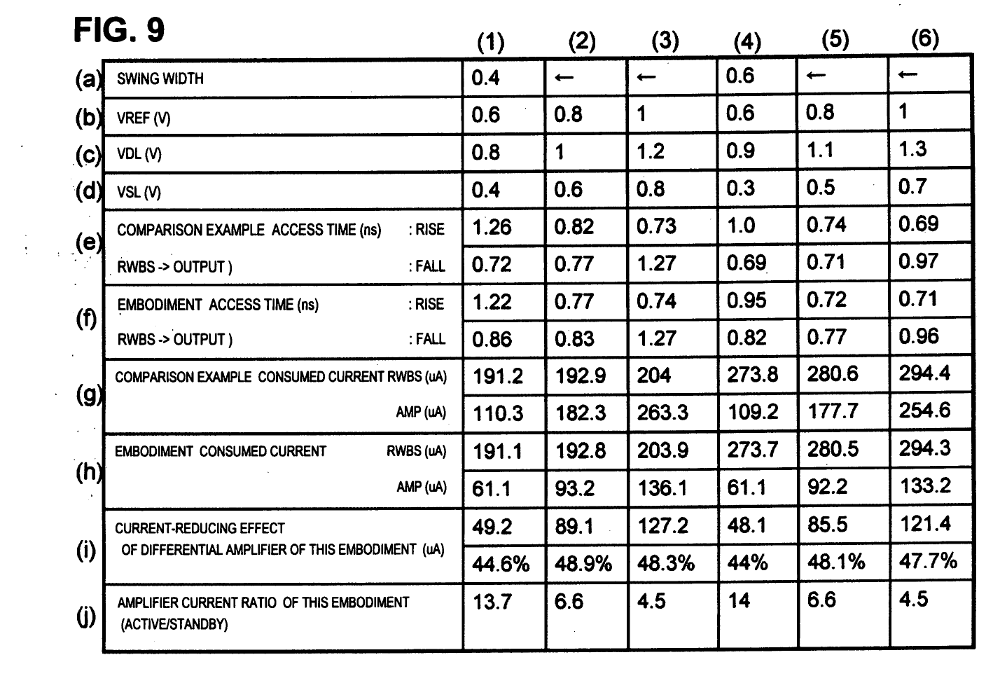

FIG. 8 is a waveform diagram illustrating results of simulations according to (a) an example for comparison purposes and (b) the first exemplary embodiment, respectively. FIG. 9 is a diagram illustrating the conditions and results of the simulations of FIG. 8 in chart form. FIG. 8(a), which is the upper diagram, illustrates the results of simulation according to the comparison example. FIG. 8(b) illustrates the results of simulation according to the first exemplary embodiment shown below the simulation results of the comparison example with the time axes (horizontal axes) of the two diagrams being in alignment. The numerals along the horizontal axis in FIG. 8 indicate time (in ns units), and the numerals along the vertical axis indicate voltage (in units of voltage V). In FIG. 8, in both (a) the comparison example and (b) the first exemplary embodiment, VDD=1.5V, VSS=0V, VDL=0.8V, VSL=0.4 V and VREF=0.6V holds. (See FIGS. 3 and 6 with regard to VDL, VSL. This is the amplitude of the small-amplitude signal that is input to the transistor 344.)

The potentials of the read/write data bus RWBS in both (a) the comparison example and (b) the first exemplary embodiment are slightly different at the near end (the position closest to the driver) and at the far end (the position farthest from the driver). However, potential rises from 0.4V of the VSL level to 0.8V of the VDL level from approximately 146 to 148 ns and from approximately 156 to 158 ns. Further, potential falls from 0.8V of the VDL level to 0.4V of the VSL level from 151 to 152 ns. In the first exemplary embodiment shown at (b), the read-data strobe signal DRLAT is placed at the high level in the intervals 146 to 148 ns, 151 to 153 ns and 156 to 158 ns in conformity with the timings at which the potential of the read/write data bus RWBS undergoes a transition. In intervals other than these (namely up to 146 ns, 148 to 151 ns, 153 to 156 ns), the read-data strobe signal DRLAT is placed at the low level. That is, by controlling the read-data strobe signal DRLAT, the current of the current source of amplifier section 41 is increased or decreased and the output impedance of the output section 42 is increased or decreased.

In both (a) the comparison example and (b) the first exemplary embodiment, the voltage of the output terminal DROUT rises from the low level (0V) to the high level (1.5V) at about 147 ns, falls at 151 ns and rises again at 157 ns. With regard to the output waveform of output terminal DROUT, it will be understood that there is no major difference between (a) the comparison example and (b) the first exemplary embodiment of FIG. 8.

The simulation results will now be described in greater detail with reference to FIG. 9. The simulation conditions are shown on lines (a) to (d) of FIG. 9, and the simulation results are shown on lines (e) to (i). Further, the current ratio [(IM+IS1)/IS1] of the amplifier section according to the first exemplary embodiment is indicated on line (j). Columns (1) to (6) indicate cases where the respective simulation conditions differ. It should be noted that the simulation conditions in FIG. 8 correspond to column (1) in FIG. 9. Regardless of the simulation conditions under which the simulations are performed, access time [see lines (e) and (f)] does not differ greatly between the first exemplary embodiment and the comparison example. However, as indicated by current consumption of the amplifier section on lines (g) and (h), current consumption of the amplifier section differs greatly between the exemplary embodiment and the comparison example. In comparison with the comparison example, current consumption of the amplifier section according to the first exemplary embodiment is one-half or less [see line (i)]. Further, if columns (1) to (3) are compared with columns (4) to (6), it will be understood that the charge/discharge current of the read/write data bus RWBS depends upon the power-source voltages of VDL and VSL and that the smaller the potential difference between VDL and VSL {i.e., the amplitude of the small-amplitude signal [the swing width on line (a)]}, the smaller the consumed current of the read/write data bus RWBS.

### Second Exemplary Embodiment

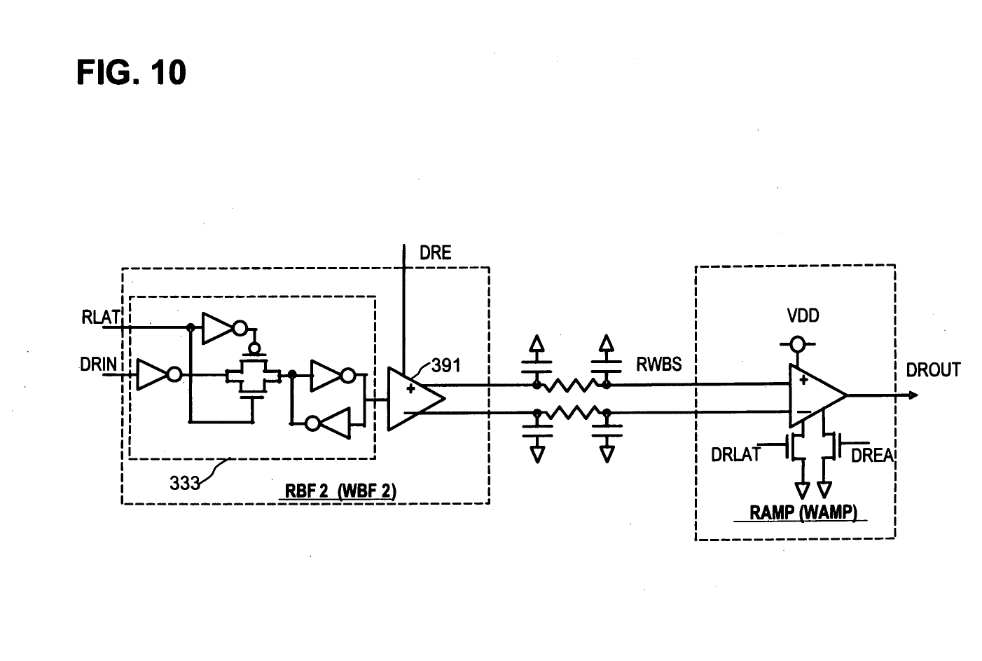

FIG. 10 is a circuit block diagram illustrating a data transmission circuit according to a second exemplary embodiment of the present invention. In FIG. 10, the small-amplitude signal transmitted on the read/write data bus RWBS is changed from the single-end signal of the first exemplary embodiment to differential signal. A differential signal driver 391 is used as the driver section of a data buffer RBF2 in the second exemplary embodiment (or WBF2; RBF2 and WBF2 correspond to read-data buffer RBF and write-data buffer WBF of the first exemplary embodiment). A non-inverted signal and an inverted signal are output from the differential signal driver 391 to respective ones of a plurality of corresponding read/write data buses RWBS. The differential signal driver 391 is controlled by the read buffer output-enable signal DRE. The differential signal driver 391 is supplied with the high-potential power source VDL and the low-potential power source VSL of the small-amplitude signal as power. The small-amplitude signal is output to the read/write data bus RWBS. As for the data receiver, the data receiver of the first exemplary embodiment can be used as is with the only change being that the gate of N-channel MOS transistor 343 (see FIG. 5) of the data receiver (RAMP or WAMP) of the first exemplary embodiment is connected to the inverted signal on the read/write data bus RWBS instead of the reference signal VREF. If it is so arranged that a differential signal is transmitted as the signal transmitted on the read/write data bus RWBS, the number of wires in the read/write data bus RWBS increases but it is possible to further reduce the amplitude of the small-amplitude signal. As a result, it is possible for the voltage between the high-potential power source VDL and the low-potential power source VSL to be made even smaller than the voltage between the high-potential power source VDL and the low-potential power source VSL of the first exemplary embodiment. Other aspects of structure and operation are similar to those of the first exemplary embodiment and need not be described again. The write-data transmission circuit also can be implemented in similar fashion using the scheme of the second exemplary embodiment.

### Third Exemplary Embodiment

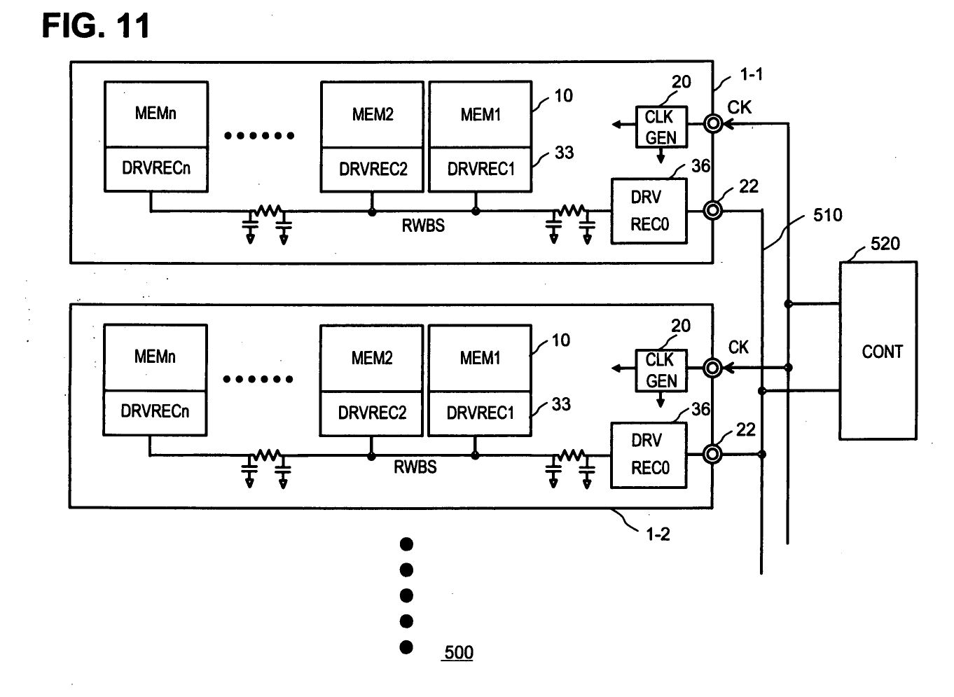

FIG. 11 is a block diagram illustrating a data transmission system according to a third exemplary embodiment of the present invention. The third exemplary embodiment includes a plurality of semiconductor devices 1-1, 1-2, . . . and a data processor 520. Although only two semiconductor devices 1-1 and 1-2 are illustrated, a larger number of semiconductor devices may be provided. Each of the semiconductor devices 1-1, 1-2 is a semiconductor device according to the first or second exemplary embodiment. The semiconductor devices 1-1, 1-2 and the data processor 520 are connected by an external data bus 510. The external data bus 510 is connected to the external I/O terminal 22 of each of the semiconductor devices 1-1, 1-2. A clock from the data processor 520 is connected to a CK terminal of each semiconductor device. Each semiconductor device is provided internally with a clock generator 20. The latter generates and outputs a timing signal necessary for operation of each component within the semiconductor device. Each semiconductor device is further provided internally with a plurality of memory cell arrays (MEM1 to MEMn) 10. Provided in correspondence with the memory cell arrays are internal-circuit-side input/output circuits (DRVREC1 to DRVRECn) 33. Provided in correspondence with each external I/O terminal 22 is an external-terminal-side input/output circuit (DRVREC0) 36. Each internal-circuit-side input/output circuit 33 and the external-terminal-side input/output circuit 36 are connected by read/write data bus RWBS. The semiconductor devices 1-1, 1-2 operate based upon command such as a read command and write command from the data processor 520.

When a write command is executed, the external-terminal-side input/output circuit 36 outputs write data, which has been sent from the external data bus 510, to the read/write data bus RWBS as a small-amplitude signal. The internal-circuit-side input/output circuit 33 provided in correspondence with the selected memory cell array 10 amplifies the small-amplitude signal by the internally provided write-data receiver WAMP. The write-data receiver WAMP increases or decreases the current of the amplifier section and increases or decreases the output impedance of the output section in synch with the write-data strobe signal DWLAT (second control signal). Write data sent up to the internal-circuit-side input/output circuit 33 is further written to the memory cell array.

When the read command is executed, the designated memory cell array 10 sends read data to the internal-circuit-side input/output circuit based upon a command from the data processor 520. The internal-circuit-side input/output circuit 33 level-converts the read data to a small-amplitude signal and outputs the signal to the read/write data bus RWBS. The external-terminal-side input/output circuit 36 amplifies this small-amplitude signal using the read-data receiver RAMP, enlarges the amplitude to the usual voltage level of a logic circuit and outputs the signal. At this time the read-data receiver RAMP increases or decreases the current of the amplifier section and increases or decreases the output impedance of the output section in synch with the read-data strobe signal DRLAT (second control signal). Read data whose amplitude has been enlarged to the usual voltage level of a logic circuit is output to the external data bus 510 in synch with the external data strobe signal that is output from a DQS terminal (not shown).

### Fourth Exemplary Embodiment

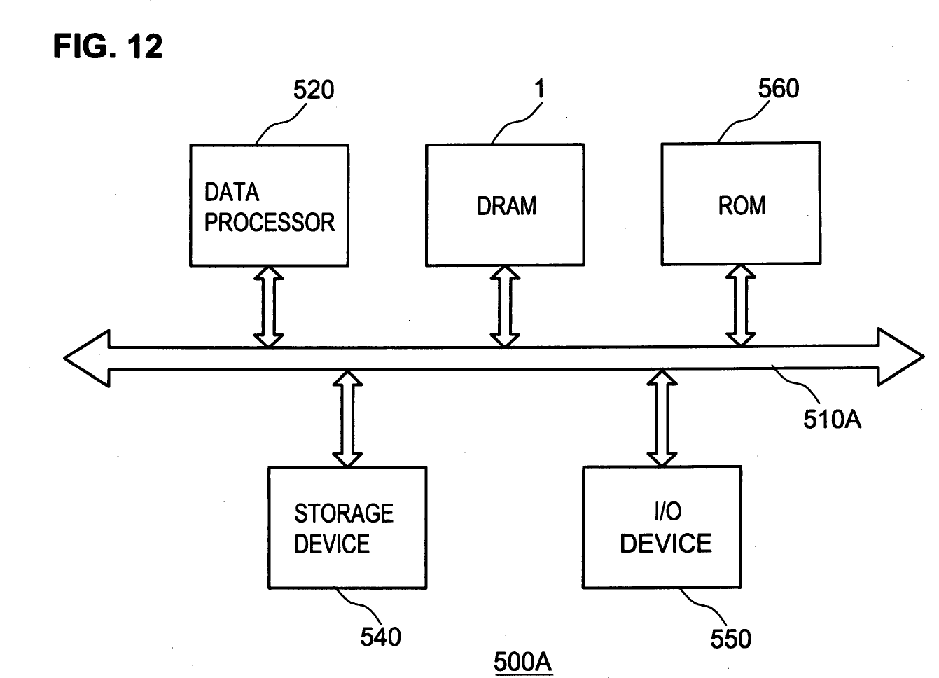

FIG. 12 is a block diagram of another data transmission system using the semiconductor device 1. A data transmissions system 500 shown in FIG. 12 includes the data processor 520 and semiconductor device (DRAM) 1 interconnected via a system bus 510A. By way of example, a microprocessor (MPU) and digital signal processor (DSP), etc., are included as the data processor 520, although the data processor 520 is not limited to such an arrangement. In order to simplify the description of FIG. 12, the data processor 520 and DRAM 1 are connected via the system bus 510A. However, it does not matter if these are connected by a local bus without relying upon the system bus 510A.

In order to simplify the description, only a single system bus 510A is shown in FIG. 12. However, system buses may be provided in serial or parallel via connectors or the like as necessary. Further, in the system shown in FIG. 12, a storage device 540, an I/O device 550 and a ROM 560 are connected to the system bus 510A. However, these are not necessarily essential structural elements. In addition, the data processor 520, DRAM 1, storage device 540, I/O device 550 and ROM 560 may each constitute a plurality of groups and may be connected by a plurality of system buses 510A that differ for every group.

A hard-disk drive, optical disk drive and flash memory, etc., can be mentioned as examples of the storage device 540. A display device such as a liquid crystal display and an input device such as a keyboard and mouse can be mentioned as an example of the I/O device 550.

It does not matter if the I/O device 550 is either an input device or an output device.

Although only one each of the structural elements illustrated in FIG. 12 is shown, this does not impose a limitation and one, two or more of the structural elements may be plural in number.

In the fourth exemplary embodiment, the controller (e.g., the data processor 520) that controls the DRAM issues various commands, which are related to data read and write access to the DRAM 1, utilizing system clocks Ck, CKB and other control signals. Upon receiving a read command from the controller, the semiconductor device 1 reads out stored information held internally and transmits this data to the system bus 510A via the first transmission line RWBS (FIG. 1). Further, upon receiving a write command from the controller, the semiconductor device 1 writes data, which has entered from the system bus 510A, to the memory cell array 10 via the first transmission line RWBS. It should be noted that the plurality of commands issued by the controller are commands (system commands) defined by [JEDEC (Joint Electron Device Engineering Council) Solid-State Technology Association], which is an industrial organization that controls semiconductor devices.

In the fourth exemplary embodiment, not only the DRAM 1 but also the storage device 540, I/O device 550 and ROM 560 can use, as the internal-data data bus, a bus that transmits data as a small-amplitude signal bidirectionally, a described in the first and second exemplary embodiments, or in one direction. Further, when the data receiver that receives the small-amplitude signal amplifies the small-amplitude signal to raise its amplitude to the signal level of an ordinary logic circuit using the data receiver described in the first or second exemplary embodiment, the current of the amplifier section can be increased or decreased and the output impedance of the output section increased or decreased in synch with the timing at which the data of the small-amplitude signal is updated. By adopting this arrangement, input and output of data can be performed at high speed and with little power consumption within each chip in response to a request from the data processor 520.

In the foregoing exemplary embodiments, an example in which transmission of data is bidirectional is described primarily. However, data transmission need not necessarily be bidirectional. In a case where data transmission is in one direction, data can be transmitted with little power consumption and at high speed in accordance with the present invention. Further, in the first to third exemplary embodiments, transmission of data between the side of the internal circuitry and the side of the external terminals is described. However, transmission of data is not limited to transmission of data between the side of the internal circuitry and the side of the external terminals and it is obvious that the invention can be used in transmission of data between internal circuits as well. Furthermore, with regard to transmission of data between semiconductor devices as well, transmission can be performed using a small-amplitude signal and the current in the amplifier section can be increased or decreased and the output impedance of the output section increased or decreased in synch with the timing at which the received data is updated.

Furthermore, transmission of a memory data signal is described in the exemplary embodiments. However, the present invention is not limited to such transmission and is also applicable to transmission of data processor data, by way of example. Furthermore, the specific form of the circuitry of the driver and receiver and the circuitry that generates the control signals are not limited to the form of the circuitry disclosed by the exemplary embodiments. For example, the control section (circuit) that generates the small-amplitude signal is not limited to the disclosures of the exemplary embodiments.

Further, the present invention, which provides a semiconductor device having a transmission line, is applicable to all semiconductor devices such as a CPU (Central Processing Unit), MCU (Micro-Control Unit), DSP (Digital Signal Processor), ASIC (Application-Specific Integrated Circuit) and ASSP (Application-Specific Standard Product). As for the product form of the semiconductor device according to the present invention, an SOC (System-On Chip), MCP (Multi-Chip Package) and POP (Package-On-Package), etc., can be mentioned. The present invention is applicable to semiconductor devices having any of these product forms and package configurations.

Further, if the transistors are field-effect transistors (FETs), then the transistors are not limited to MOS (Metal Oxide Semiconductor)-type transistors and the invention is applicable to various FETs such as a MIS (Metal-Insulator Semiconductor) and TFT (Thin-Film Transistor), etc. Furthermore, some of the transistors may be bipolar transistors. The transistors may be other than FETs.

It should be noted that a P-channel MOS transistor (P-type channel MOS transistor) is a typical example of a transistor of first conductivity type and an N-channel MOS transistor (N-type channel MOS transistor) is a typical example of a transistor of a second conductivity type.

Each disclosure of the aforementioned Patent Documents is incorporated herein by reference thereto.

It should be noted that other objects, features and aspects of the present invention will become apparent in the entire disclosure and that modifications may be done without departing the gist and scope of the present invention as disclosed herein and claimed as appended herewith. Also it should be noted that any combination or selection of the disclosed and/or claimed elements, matters and/or items may fall under the modification aforementioned.

What is claimed is:

1. A semiconductor device comprising:
a first amplifier comprising an amplifier section that amplifies an input signal and an output section including an input node coupled to an output node of the amplifier section; and
in relation to sensing of one item of information, a first control signal that controls activation of said first amplifier and a second control signal synchronized to transitions of the input signal;
wherein the input signal has a first differential voltage indicated by a first potential corresponding to a first item of information and a second potential corresponding to a second item of information;
said first amplifier outputs a second differential voltage, which has an absolute value larger than that of the first differential voltage, from the output node of the output section;
the amplifier section includes a first current source is used to sense the input signal, controlled by the first control signal, and a second current source is used to sense the input signal, which is a current source larger than the first current source, controlled by the second control signal;
the output section includes, as output impedance values thereof, a first impedance value and a second impedance value either of which is selected by the second control signal, the second impedance value having an absolute value smaller than that of the first impedance value;
the amplifier section is activated by the first control signal;
the output section outputs, as the first impedance value, an output signal having the second differential voltage corresponding to the input signal having the first differential voltage; and
with said first amplifier in the activated state, the amplifier section and the output section, using the second current source and the second impedance value under the control of the second control signal, the amplifier section and the output section output, as the second impedance value, the output signal having the second differential voltage corresponding to transitions of the input signal having the first differential voltage.

2. The semiconductor device according to claim 1, wherein the amplifier section includes a differential pair including a first input terminal coupled to the input signal;
the output section includes an inverter in which a first and a second transistors of mutually different conductivity types are serially coupled;
the first and the second current sources are each coupled to the differential pair; and
the inverter has the first and the second impedance values.

3. The semiconductor device according to claim 1, wherein voltage that is output from the output node of the amplifier section is a third differential voltage between the first and the second differential voltages.

4. The semiconductor device according to claim 1, wherein the input signal comprises complementary signals indicated by a first and a second input signals indicating one item of information by mutually different complementary potentials;
the amplifier section includes a differential pair having a first and a second input terminals to which the first and the second input signals are respectively input;
the output section includes an inverter in which a first and a second transistors of mutually different conductivity types are serially coupled; and
the inverter has the first and the second impedance values.

5. The semiconductor device according to claim 1, further comprising a first circuit, which is supplied with a voltage smaller than the second differential voltage, and generating the input signal;
wherein the first circuit is controlled by the first control signal.

6. The semiconductor device according to claim 5, wherein an output terminal of said first circuit and an input terminal of said first amplifier are coupled by a transmission line that transmits data within the semiconductor device;
said first circuit is a driver circuit that outputs data, which has been updated in synch with the second control signal, to the transmission line as a small-amplitude signal; and said first amplifier is a receiver circuit that receives the small-amplitude signal.

7. The semiconductor device according to claim 2, wherein the differential pair includes a second input terminal; and
a reference voltage signal having a potential intermediate the first and the second potentials is coupled to the second input terminals.

8. The semiconductor device according to claim 7, wherein the differential pair includes:
a first differential transistor including a source coupled to the first and the second current sources, a gate coupled to the first input terminal and a drain coupled to a first load circuit; and
a second differential transistor including a source coupled in common with the source of said first differential transistor and coupled to the first and the second current sources, a gate coupled to the second input terminal and a drain coupled to a second load circuit.

9. The semiconductor device according to claim 7, wherein the first current source includes a first power source transistor the electrical conduction/non-conduction of which is controlled by the first control signal; and
the second current source includes a second power source transistor the electrical conduction/non-conduction of which is controlled by the second control signal, and a third power source transistor, which is provided between the second power source transistor and the differential pair, the electrical conduction/non-conduction of which is controlled by the first control signal.

10. The semiconductor device according to claim 2, wherein the output section further includes:
a first variable resistor coupled in series with the first transistor between the output node and a first power source; and
a second variable resistor coupled in series with the second transistor between the output node and a second power source;
resistance values of the first and second variable resistors being controlled by the second control signal.

11. A data transmission system comprising:
a transmitting unit that updates data in synch with a clock and transmits the data to a transmission line as a small-amplitude signal;
a receiving unit, which is coupled to the transmission line, including an amplifier section that receives and amplifies the small-amplitude signal, and an output section that includes an input node coupled to an output node of the amplifier section and outputs a signal from an output node as a data signal having an amplitude value the voltage whereof is larger than that of the small-amplitude signal; and
a reception control unit which, in relation to sensing of one item of information, and in an interval in which the amplifier section is activated, increases and decreases a current, which passes through the amplifier section, in synch with the clock, and increases and decreases an output impedance value of the output section in synch with the clock.

12. The system according to claim 11, wherein said reception control unit exercises control so as to increase the current of the amplifier section at timings at which the logic level of the small-amplitude signal received by the amplifier section undergoes a transition, and decrease the current of the amplifier section at timings at which the logic level of the small-amplitude signal received by the amplifier section undergoes does not undergo a transition.

13. The system according to claim 11, wherein said reception control unit exercises control so as to decrease the output impedance value of the output section at timings at which the logic level of the signal that is output by the output section undergoes a transition, and increase the output impedance value of the output section at timings at which the logic level of the signal that is output by the output section undergoes a transition.

14. The system according to claim 11, further comprising a controller that controls said data transmission system;
wherein said transmitting unit transmits the data to said receiving unit based upon a command from said controller; and
said receiving unit outputs the data, which has been received from said transmitting unit, to said controller.

15. The system according to claim 14, wherein said system includes a plurality of semiconductor devices each of which internally includes said transmitting unit, said receiving unit and said reception control unit; and
the plurality of semiconductor devices and the controller are coupled by a external bus, and said controller control data transmission of the plurality of semiconductor devices.

16. The system according to claim 11, further including a data storage unit coupled to said transmitting unit, wherein updating of the data changes over a plurality of items of stored data possessed by said data storage unit.

17. A method of controlling a semiconductor device comprising an input signal having a first differential voltage, and a first amplifier having as an operating voltage a second differential voltage larger than the first differential voltage, said method comprising:
activating the first amplifier by a first control signal; and
in relation to sensing of a first item of information, and in a state in which activation of the first amplifier is maintained, controlling sensing capability by raising capability of a current source is used to sense the input signal that drives the first amplifier, by a second control signal related to transitions of the input signal, and controlling, by the second control signal, the impedance value of a driver receiving a signal, which has been output to an output node of the first amplifier, at an input node and outputting the signal from an output node as a signal having the second differential voltage.

18. The method according to claim 17, wherein the semiconductor device includes a transmitting unit, which is supplied with a voltage smaller than the second differential voltage, generating the input signal as a small-amplitude signal having the first differential voltage, and a transmission line that transmits the input signal up to the first amplifier;
the transmitting unit outputs the input signal to the transmission line in synch with the second control signal; and
on the basis of the second control signal, the first amplifier increases the current value of the current source in correspondence with timings at which the logic level of the input signal received by the first amplifier undergoes a transition, and decreases the current value of the current source in correspondence with timings at which the logic level of the input signal does not undergo a transition.

19. The method according to claim 17, wherein the first amplifier includes an amplifier section that amplifies the input signal, and an output section having a driver for receiving an internal signal sent by the amplifier section; and
control is exercised in such a manner that:
in a state in which activation of the first amplifier is maintained, impedance of the output section is decreased based upon the second control signal at timings at which the logic level of the output of the amplifier section undergoes a transition in correspondence with timings at which the logic level of the input signal undergoes a transition; and
in a state in which activation of the first amplifier is maintained, the output impedance of the output section is increased at timings at which the logic level of the output of the amplifier section does not undergo a transition.

20. The method according to claim 19, wherein the amplifier section amplifies the input signal, which has the first differential value, to a third differential value between the first and second differential values; and
the output section amplifies the third differential voltage to the second differential voltage.
